(19) United States
(12) Patent Application Publication
(10) Pub. No.: US 2013/0062639 A1
(43) Pub. Date: Mar. 14, 2013

(54) METHOD FOR FABRICATING LIGHT EMITTING DIODE (LED) DEVICES HAVING OUTPUT WITH SELECTED CHARACTERISTICS

(71) Applicants: TRUNG TRI DOAN, Baoshan Hsinchu (TW); JUI-KANG YEN, Taipei City (TW)

(72) Inventors: TRUNG TRI DOAN, Baoshan Hsinchu (TW); JUI-KANG YEN, Taipei City (TW)

(73) Assignee: SEMILEDS OPTOELECTRONICS CO., LTD., Miao-Li County (TW)

(21) Appl. No.: 13/229,824

(22) Filed: Sep. 12, 2011

(51) Int. Cl. H01L 33/50

(52) U.S. Cl. 257/98; 438/7; 257/E33.061; 257/E33.073

(57) ABSTRACT

A method for fabricating a light emitting diode (LED) device includes the steps of forming (or providing) a plurality of LED dice, forming a plurality of wavelength conversions layers, and then evaluating at least one electromagnetic radiation emission characteristic of each LED die and at least one color characteristic of each wavelength conversion layer. The method also includes the steps of comparing the evaluated characteristic of each LED die and the evaluated characteristic of each wavelength conversion layer to a database, selecting a selected LED die and a selected wavelength conversion layer based on the evaluating and comparing steps, and then attaching the selected wavelength conversion layer to the selected LED die.

### BACKGROUND

This disclosure relates generally to light emitting diodes (LED) and more particularly to methods for fabricating light emitting diode (LED) devices.

Light emitting diode (LED) devices have been developed that produce white light. In order to produce white light, a blue (LED) die can be used in combination with a wavelength conversion layer, such as a phosphor layer formed on the surface of the die. The electromagnetic radiation emitted by the blue (LED) die excites the atoms of the wavelength conversion layer, which converts some of the electromagnetic radiation in the blue wavelength spectral region to the yellow wavelength spectral region. The ratio of the blue to the yellow can be manipulated by the composition and geometry of the wavelength conversion layer, such that the output of the light emitting diode (LED) device appears to be white light.

In this type of light emitting diode (LED) device, the characteristics of the white light produced by the device are determined by the electromagnetic radiation emitted by the blue LED die and by the wavelength conversion properties of the wavelength conversion layer. For example, the color composite of the white light depends upon the spectral distributions of electromagnetic radiation produced by the blue LED die and the wavelength conversion layer. Any variations in these spectral distributions can vary the color composite of the white light produced by the light emitting diode (LED) device. Because of the variations in the configurations of the blue LED die and the wavelength conversion layer, the white light can have an undesirable color balance and lack the characteristics of a true color rendition.

It is difficult to fabricate white light emitting diode (LED) devices with consistent color balance because any variations in the fabrication process can change the outputs of the light emitting diode (LED) dice and the wavelength conversion layers. The present disclosure is directed to a method for fabricating light emitting diode (LED) devices having an output with selected characteristics. For example, using the method a light emitting diode (LED) device can be fabricated that produces white light having a desired color balance, a desired color temperature or a desired spectral distribution.

### SUMMARY

A method for fabricating a light emitting diode (LED) includes the steps of forming (or providing) a LED die, forming a wavelength conversion layer, and then evaluating at least one characteristic of the LED die and at least one characteristic of the wavelength conversion layer. For example, the evaluated characteristic for the LED die can be peak wavelength or wavelength range, and the evaluated characteristic for the wavelength conversion layer can be a color characteristic at the peak wavelength or the wavelength range. The method also includes the steps of comparing the evaluated characteristic of the LED die to a first database having a first criteria, and the evaluated characteristic of the wavelength conversion layer to a second database having a second criteria, and then attaching the selected wavelength conversion layer to the selected LED die provided the first criteria and the second criteria are met.

For fabricating a light emitting diode (LED) device configured to emit white light having a particular color temperature, the method can include the steps of: forming (or providing) a LED die configured to emit electromagnetic radiation in a first spectral region; evaluating and comparing the electromagnetic radiation in the first spectral region to a first database having a first criteria; forming a wavelength conversion layer configured to convert the electromagnetic radiation in the first spectral region to electromagnetic radiation in a second spectral region; evaluating and comparing the electromagnetic radiation in the second spectral region to a second database having a second criteria; and following the evaluating and comparing step, attaching the wavelength conversion layer to the LED die provided the electromagnetic radiation in the first spectral region emitted by the LED die meets the first criteria and the electromagnetic radiation in the second spectral region converted by the wavelength conversion layer meets the second criteria.

A light emitting diode (LED) device fabricated using the method can include a LED die that has been evaluated for wavelength characteristics, and a wavelength conversion layer that has been evaluated for color characteristics at a particular wavelength range to produce an electromagnetic radiation output having a particular color temperature. In addition, the color temperature can be consistently repeated even with variations in the fabrication processes for LED dice and wavelength conversion layers.

### BRIEF DESCRIPTION OF THE DRAWINGS

Exemplary embodiments are illustrated in the referenced figures of the drawings. It is intended that the embodiments and the figures disclosed herein are to be considered illustrative rather than limiting.

FIG. 1 is a flow diagram illustrating steps in a method for fabricating a light emitting diode (LED) device having selected electromagnetic radiation output characteristics;

FIG. 2A is a schematic cross sectional view illustrating a LED die following a die forming step of the method;

FIG. 2B is a schematic cross sectional view of a wavelength conversion layer following a layer forming step of the method;

FIG. 2C is a schematic cross sectional view of an alternate embodiment wavelength conversion layer attached to a plate;

FIG. 2D is a schematic cross sectional view of another alternate embodiment wavelength conversion layer attached to a lens;

FIG. 3A is a schematic cross sectional view illustrating a LED die evaluating step of the method;

FIG. 3B is a schematic cross sectional view illustrating a wavelength conversion layer evaluating step of the method;

FIG. 4 is a flow diagram illustrating a comparing and selecting step of the method;

FIG. 5 is an exemplary emission spectrum for the output of a light emitting diode (LED) device constructed using the method;

FIG. 6 is a schematic cross sectional view illustrating an attaching step of the method;

FIG. 7 is a schematic cross sectional view illustrating a light emitting diode (LED) device fabricated using the method;

FIGS. 8A and 8B are a CIE chromaticity diagram and an emission spectrum, respectively, corresponding to a first LED device fabricated using the method;

FIGS. 9A and 9B are a CIE chromaticity diagram and an emission spectrum, respectively, corresponding to a second LED device fabricated using the method; and

FIGS. 10A and 10B are a CIE chromaticity diagram and an emission spectrum, respectively, corresponding to a third LED device fabricated using the method.

### DETAILED DESCRIPTION

It is to be understood that when an element is stated as being “on” another element, it can be directly on the other element or intervening elements can also be present. However, the term “directly” means there are no intervening elements. In addition, although the terms “first”, “second” and “third” are used to describe various elements, these elements should not be limited by the term. Also, unless otherwise defined, all terms are intended to have the same meaning as commonly understood by one of ordinary skill in the art.

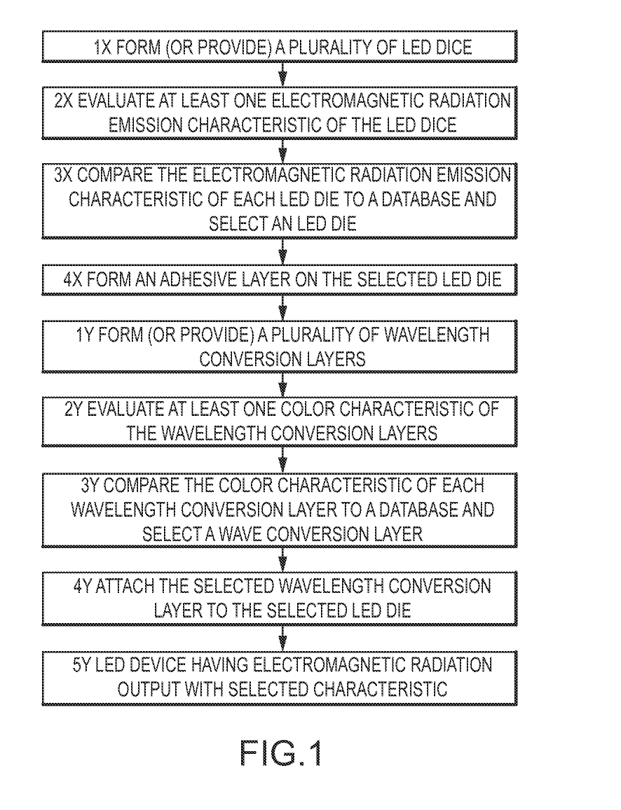

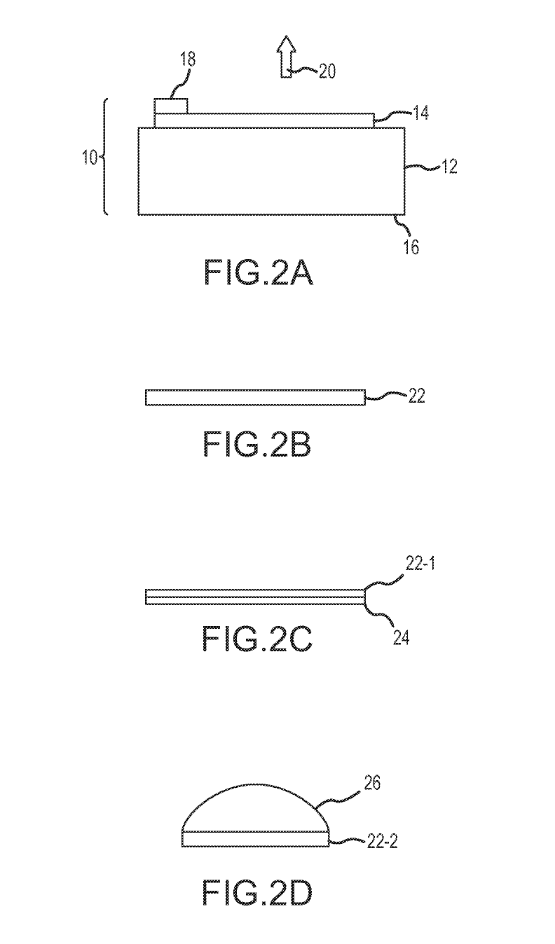

Referring to FIG. 1, steps in a method for fabricating a light emitting diode (LED) devices having an output with selected characteristics is illustrated. As shown by block 1X of FIG. 1, the method includes the step of forming (or providing) a plurality of LED dice. FIG. 2A illustrates an exemplary LED die 10 in the form of a vertical light emitting diode (VLED) die.

As shown in FIG. 2A, the LED die 10 can include a conductive substrate 12 having a first electrode 16 (e.g., P-electrode), and a semiconductor structure 14 on the conductive substrate 12 having a second electrode 18 (e.g., N-electrode). The LED die 10 can be formed at the wafer level using processes known in the art, such as disclosed in U.S. Pat. No. 7,195,944 B2 to Tran et al., and U.S. Pat. No. 7,615,789 B2 to Tran, both of which are incorporated herein by reference. The LED die 10 can also be provided by a manufacturer such as Semileds Corporation of Boise Id. and Hsinchu County Taiwan.

The LED die 10 can be configured to emit electromagnetic radiation 20 having desired characteristics, such as electromagnetic radiation in a desired spectral region. For example, the LED die 10 can be configured to emit electromagnetic radiation from the visible spectral region (e.g., 400-770 nm), the violet-indigo spectral region (e.g., 400-450 nm), the blue spectral region (e.g., 450-490 nm), the green spectral region (e.g., 490-560 nm), the yellow spectral region (e.g., 560-590 nm), the orange spectral region (e.g., 590-635 nm) or the red spectral region (e.g., 635-700 nm).

As shown in FIG. 1, the method also includes the step shown in block 1Y of forming or providing a plurality of wavelength conversion layers. Each wavelength conversion layer 22 (FIG. 2B) includes a material configured to convert at least some of the electromagnetic radiation emitted by the LED die 10 into electromagnetic radiation having a different wavelength range. For example, each wavelength conversion layer 22 (FIG. 2B) can include a layer of material configured to convert the electromagnetic radiation emitted by the LED die 10 into electromagnetic radiation having a higher wavelength. For example, if the LED die 10 emits electromagnetic radiation in a blue spectral range, the wavelength conversion layer 22 (FIG. 2B) can include a layer containing a phosphor compound for converting some of this radiation to a yellow spectral range. Suitable phosphor compounds are known in the art and further described in the previously cited patents to Tran et al. and Tran.

As shown in FIG. 2B, the wavelength conversion layer 22 can comprise a base material containing a wavelength conversion material. For example, the wavelength conversion material can be incorporated into a base material, such as plastic, glass or an adhesive polymer using a mixing process to form a viscous mixture, which can then be cured into solid form. Exemplary base materials include silicone and epoxy in liquid or viscous form, which can be mixed with the wavelength conversion material in a specific ratio. The mixture can then be applied to a release film using a coating process such as dip coating, rod coating, blade coating, knife coating, air knife coating, Gravure coating, roll coating or slot and extrusion coating. Further, the wavelength conversion layer 22 can comprise a single layer or multiple layers formed using multiple coating processes. Exemplary coating processes are further described in Chapter 1 (pages 1-20) of Modern Coating And Drying Technology, by Edward D. Cohen, entitled “Choosing The Coating Method”, which is incorporated herein by reference. An exemplary release film comprises a fluoropolymer resin manufactured by AGC Chemicals Americas, Inc. under the trademark FLUON. Following a curing process to solidify the mixture, the wavelength conversion layer 22 in solid form can be separated from the release film using a suitable process such as peeling.

As shown in FIG. 2C, rather than being incorporated into a base material, a separate wavelength conversion layer 22-1 can be formed on a transparent base 24, such as a plastic, glass or adhesive polymer plate or lens, using a suitable process such as spraying, dipping, spin coating, rolling, electro deposition or vapor deposition to a desired thickness. Similarly, as shown in FIG. 2D, a wavelength conversion layer 22-2 can be formed on a transparent lens 26.

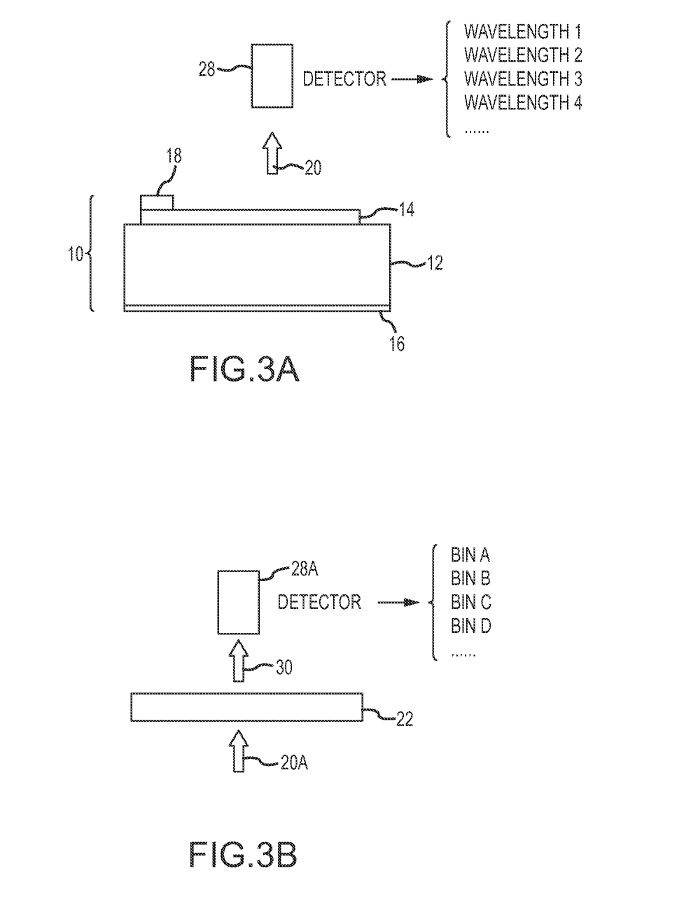

As shown in FIG. 1, the method also includes the step shown in block 2X of evaluating at least one electromagnetic radiation emission characteristic of the LED dice 10. As shown in FIG. 3A, the evaluating step can be performed by directing the electromagnetic radiation output 20 of the LED die 10 through a detector 28. For example, the detector 28 can be configured to detect a wavelength range or a peak wavelength. In FIG. 3A the wavelength characteristics of each LED die 10 are categorized as Wavelength 1, Wavelength 2, Wavelength 3, Wavelength 4 to Wavelength n. Suitable detectors are commercially available from Instrument Systems (CAS 140B), or Ocean Optics (USB 2000) or Wei-Min Industrial (LED-638HC).

As shown in FIG. 1, the method also includes the step shown in block 2Y of evaluating at least one color characteristic of the wavelength conversion layers 22 (FIG. 2B), 22-1 (FIG. 2C) or 22-2 (FIG. 2D). As shown in FIG. 3B, the evaluating step can be performed by directing a specified electromagnetic radiation output 20A from a suitable light source (e.g., a LED die equivalent to LED die 10) through the wavelength conversion layer 22 to produce electromagnetic radiation output 30. During the evaluating step, the specified electromagnetic radiation output 20A can have an optimal wavelength range, which in theory is approximately equal to the wavelength range for the electromagnetic radiation output 20 of the LED die 10. After passing through the wavelength conversion layer 22 (FIG. 3B), the electromagnetic radiation output 30 comprises a portion of the specified electromagnetic radiation output 20A and electromagnetic radiation produced by the wavelength converting layer 22 in a wavelength range. This electromagnetic radiation output 30 can then be directed through another detector 28A. The detector 28A can be configured to detect the spectrum of the electromagnetic radiation output 30 and convert it into color data (e.g., CIE(x . . . y) or CIE(u′, v′)). The detector 28A can be a commercially available unit as previously described for detector 28. In FIG. 3B, the color characteristics of each wavelength conversion layer 22 being evaluated during the evaluating step, are categorized as Bin A, Bin B, Bin C, Bin D to Bin n.

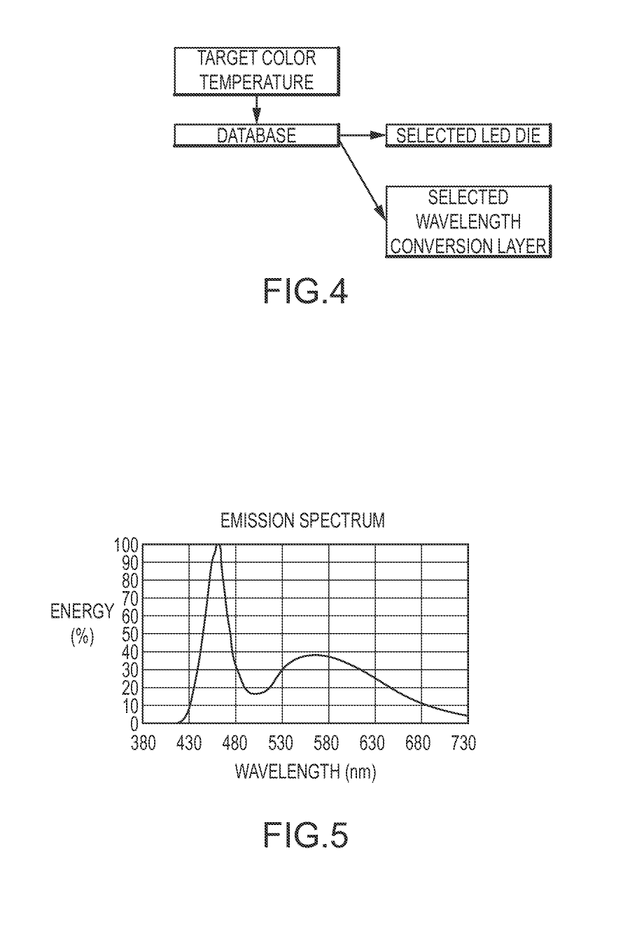

As shown in FIG. 1, the method also includes the step shown in block 3X of comparing the electromagnetic radiation emission characteristic of each LED die 10 to a database and selecting a LED die 10, and the step shown in block 3Y of comparing the color characteristic of each wavelength conversion layer to a data base and selecting a wavelength conversion layer 22. Only a LED die 10 that meets certain criteria is selected for coupling with a wavelength conversion layer 22 that has also been evaluated for color characteristics. As shown in FIG. 4, the evaluating step can be performed by selecting a LED die 10 that meets criteria in the database such as an electromagnetic radiation output for producing a target color temperature. Similarly, the selected wavelength conversion layer 22 will have met criteria in the database relating to its color converting characteristics in combination with output characteristics of the selected LED die 10. Each LED die is in effect paired to a corresponding wavelength conversion layer 22 to achieve a desired electromagnetic radiation output, such as white light having a particular color temperature. For example, FIG. 5 shows an exemplary emission spectrum for white light from a LED die configured to emit light in the blue spectral region and a wavelength conversion layer configured to emit light in the yellow spectral region.

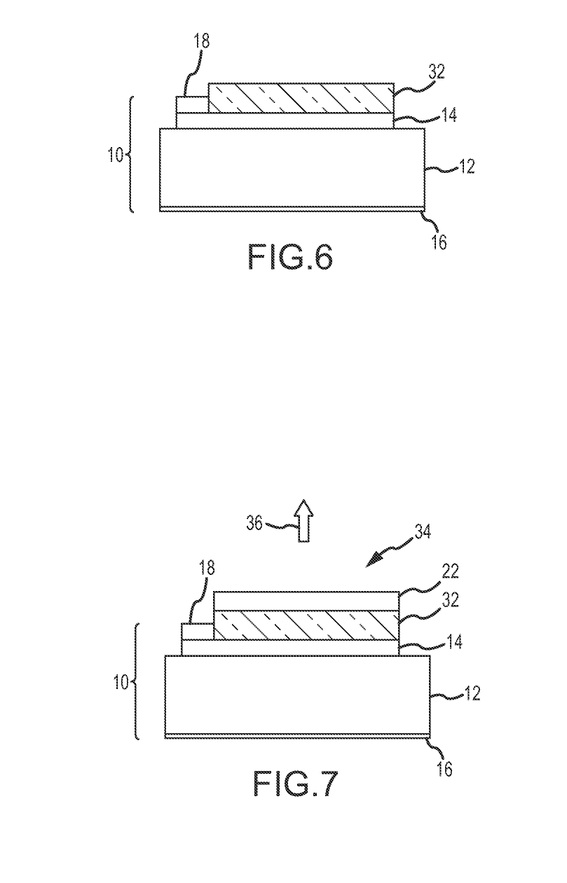

As shown in FIG. 1, the method also includes the step shown in block 4X of forming an adhesive layer on the selected LED die, and the step shown in block 4Y of attaching the selected wavelength conversion layer to the selected LED die. FIG. 6 illustrates an adhesive layer 32 formed on the LED die 12 and FIG. 7 illustrates the wavelength conversion layer 22 following attachment to the LED die 12. The adhesive layer 32 can comprise a suitable adhesive formed on the LED using a suitable process such as screen printing, spin coating, nozzle deposition or spraying. Suitable adhesives include silicone, epoxy and acrylic glue.

As shown in block 5Y of FIG. 1, the method produces a LED device having electromagnetic radiation output with selected characteristics. As shown in FIG. 7, the light emitting diode (LED) device 34 includes the selected LED die 10 and the selected wavelength conversion layer 22. In addition, the light emitting diode (LED) device 34 produces an electromagnetic radiation output 36. This electromagnetic radiation output 36 can be selected to achieve a perceived light color for the output of the light emitting diode (LED) device 34. For example, the LED die 10 and the wavelength conversion layer 22 can be configured such that the light emitting diode (LED) device 34 emits a perceived white light having a selected color temperature and chromaticity characteristics. In the art, white light can have many degrees of white that are described by a Kelvin temperature. Color temperatures between 4750-9000 K are called cool colors (blueish white), while color temperatures between 2,600-3,700 K are called warm colors (yellowish white through red). Neutral or natural white (3700 K to 4750 K), which is also known as full spectrum light, simulates the bluish white color and perceived brightness of daylight. The LED die 10 and the wavelength conversion layer 22 can also be configured such that the light emitting diode (LED) device 34 emits light of a different color, such as red, amber/yellow or green, and light having desired chromaticity characteristics. Because the LED die 10 and the wavelength conversion layer 22 have been evaluated and coupled based on their emission characteristics, the characteristics of the electromagnetic radiation output 36 will also meet criteria, such as white light having a desired spectral distribution, a desired color temperature and a desired color balance.

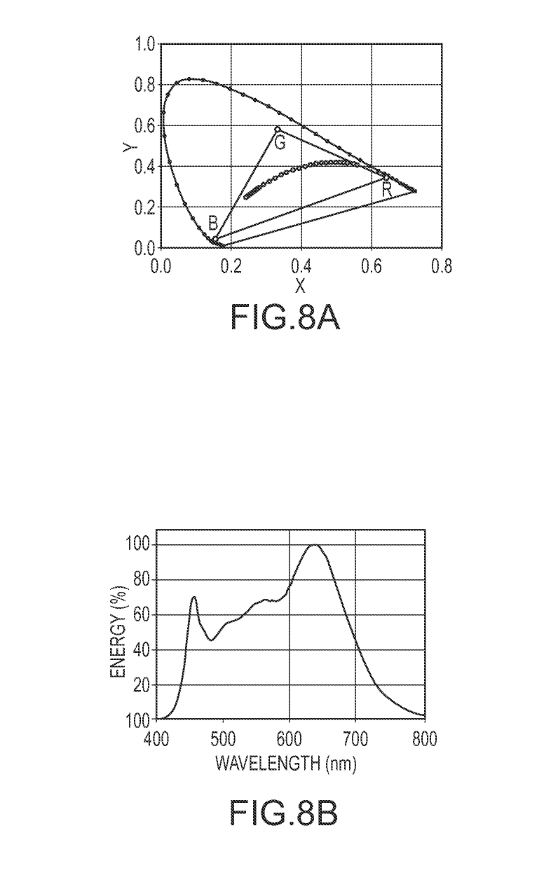

The wavelength conversion layer 22 can comprise a single layer or multiple layers of material. U.S. Pat. No. 7,781,783 B2 to Yen et al., which is incorporated herein by reference, discloses different combinations for multiple wavelength conversion layers. FIGS. 8A and 8B are an International Commission on Illumination (Commission Internationale de l'Eclairage, or CIE) chromaticity diagram and an emission spectrum, respectively, corresponding to a LED device having a red fluorescent material in a first wavelength conversion layer and green a fluorescent material in a second wavelength conversion layer in combination with a blue LED die.

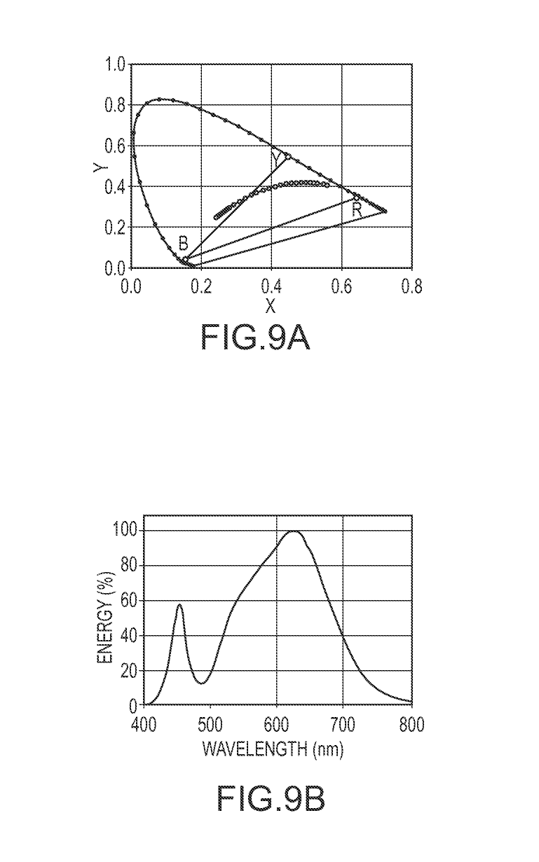

FIGS. 9A and 9B are a CIE chromaticity diagram and an emission spectrum, respectively, corresponding to a LED device having a red fluorescent material in a first wavelength conversion layer and a yellow fluorescent material in a second wavelength conversion layer in combination with a blue LED die.

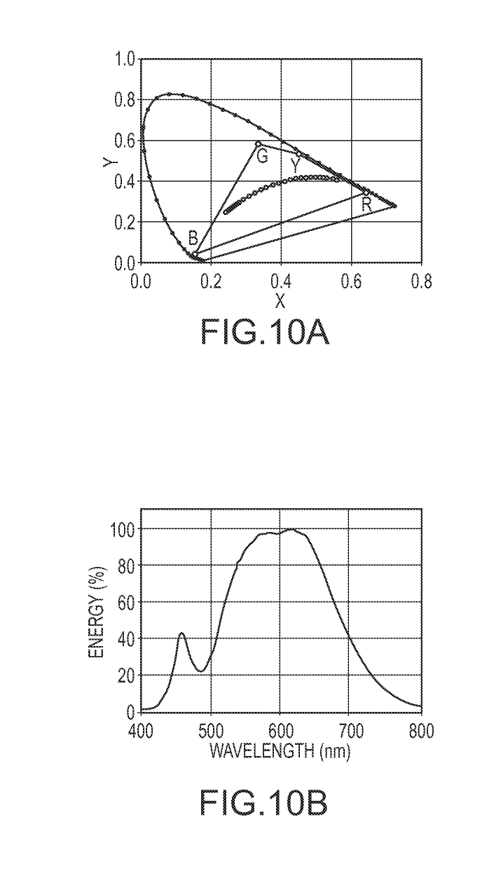

FIGS. 10A and 10B are a CIE chromaticity diagram and an emission spectrum, respectively, corresponding to a LED device having a red fluorescent material in a first wavelength conversion layer and a yellow-green fluorescent material in a second wavelength conversion layer in combination with a blue LED die.

Thus the disclosure describes an improved method for fabricating light emitting diode (LED) devices having selected electromagnetic radiation output characteristics. While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

What is claimed is:

1. A method for fabricating a light emitting diode (LED) device comprising:
forming or providing a plurality of LED dice;
forming a plurality of wavelength conversion layers;
evaluating an electromagnetic radiation emission output from the LED dice for a wavelength range and a peak wavelength;
evaluating a color characteristic of the wavelength conversion layers at the wavelength range and the peak wavelength;
comparing the electromagnetic radiation emission output for each LED die and the color characteristic for each wavelength conversion layer to a database;
selecting a selected LED die and a selected wavelength conversion layer based on the evaluating and comparing steps; and
attaching the selected wavelength conversion layer to the selected LED die.

2. The method of claim 1 wherein the forming the wavelength conversion layers step comprises mixing a wavelength conversion material with a base material to form a mixture, coating the mixture on a release film, curing the mixture and separating a wavelength conversion layer from the release film.

3. The method of claim 2 wherein the coating the mixture on the release film step comprise a process selected from the group consisting of dip coating, rod coating, blade coating, knife coating, air knife coating, Gravure coating, roll coating, and slot and extrusion coating.

4. The method of claim 1 wherein each wavelength conversion layer comprises a plastic, glass or adhesive polymer containing a phosphor compound.

5. The method of claim 1 wherein each wavelength conversion layer comprises a deposited layer on a plate or a lens containing a phosphor compound.

6. The method of claim 1 wherein the LED dice are configured to emit electromagnetic radiation in the blue spectral region, the wavelength conversion layers are configured to convert the electromagnetic radiation to the yellow spectral region and an output of the LED device comprises white light.

7. A method for fabricating a light emitting diode (LED) device comprising:
forming or providing a LED die configured to emit electromagnetic radiation in a first spectral region;
evaluating and comparing the electromagnetic radiation in the first spectral region to a first database having a first criteria;
forming a wavelength conversion layer configured to convert the electromagnetic radiation in the first spectral region to electromagnetic radiation in a second spectral region different from the first spectral region;
evaluating and comparing the electromagnetic radiation in the second spectral region to a second database having a second criteria; and
following the evaluating and comparing step, attaching the wavelength conversion layer to the LED die provided the electromagnetic radiation in the first spectral region emitted by the LED die meets the first criteria and the electromagnetic radiation in the second spectral region converted by the wavelength conversion layer meets the second criteria so that an output of the light emitting diode (LED) device comprises white light having a selected color temperature.

8. The method of claim 7 wherein the first spectral region comprises a blue spectral region and the second spectral region comprises a yellow spectral region.

9. The method of claim 7 wherein the color temperature is selected from the group consisting of warm white (2600-3700 K), neutral white (3700-4750 K) and cool white (4750-9000 K).

10. The method of claim 7 wherein the evaluating step for the LED die is performed using a detector configured to detect a peak wavelength and a wavelength range.

11. The method of claim 7 wherein the evaluating step for the wavelength conversion layer is performed using a detector configured to detect a wavelength spectrum and to convert the wavelength spectrum into color data.

12. The method of claim 7 wherein the forming the wavelength conversion layer step comprises mixing a wavelength conversion material with a base material to form a mixture, coating the mixture on a release film, curing the mixture and separating the wavelength conversion layer from the release film.

13. The method of claim 12 wherein the coating the mixture on the release film step comprise a process selected from the group consisting of dip coating, rod coating, blade coating, knife coating, air knife coating, Gravure coating, roll coating, and slot and extrusion coating.

14. The method of claim 7 wherein the attaching step is performed by forming an adhesive layer on the LED die.

15. The method of claim 7 wherein the wavelength conversion layer comprises a plastic, glass or adhesive polymer containing a phosphor compound.

16. The method of claim 7 wherein the wavelength conversion layer comprises a deposited layer on a plate or a lens containing a phosphor compound.

17. The method of claim 7 wherein the wavelength conversion layer comprises multiple layers each configured to convert the electromagnetic radiation in the first spectral region to a different spectral region.

18. The method of claim 17 wherein the multiple layers include a red fluorescent material in a first wavelength conversion layer and green a fluorescent material in a second wavelength conversion layer.

19. The method of claim 17 wherein the multiple layers include a red fluorescent material in a first wavelength conversion layer and a yellow fluorescent material in a second wavelength conversion layer.

20. The method of claim 17 wherein the multiple layers include a red fluorescent material in a first wavelength conversion layer and a yellow-green fluorescent material in a second wavelength conversion layer.

21. A light emitting diode (LED) device comprising:
a LED die that has been evaluated for wavelength characteristics including a peak wavelength and a wavelength range; and
a wavelength conversion layer that has been evaluated for color characteristics at the peak wavelength and the wavelength range to produce an electromagnetic radiation output having a particular color temperature.

22. The light emitting diode (LED) device of claim 21 wherein the wavelength range comprises a blue spectral region and the color characteristic falls within the yellow spectral region.

23. The light emitting diode (LED) device of claim 21 wherein the wavelength conversion layer comprises a phosphor compound.

24. The light emitting diode (LED) device of claim 21 wherein the wavelength conversion layer comprises multiple layers including a red fluorescent material in a first wavelength conversion layer and green a fluorescent material in a second wavelength conversion layer.

25. The light emitting diode (LED) device of claim 21 wherein the wavelength conversion layer comprises multiple layers including a red fluorescent material in a first wavelength conversion layer and a yellow fluorescent material in a second wavelength conversion layer.

26. The light emitting diode (LED) device of claim 21 wherein the wavelength conversion layer comprises multiple layers including a red fluorescent material in a first wavelength conversion layer and a yellow-green fluorescent material in a second wavelength conversion layer.
